(19) United States
(12) Patent Application Publication
(10) Pub. No.: US 2008/0115830 A1
(43) Pub. Date: May 22, 2008

(54) Test device for solar concentrator module

(75) Inventors: Hwa-Yuh Shin, Taoyuan County (TW); Hung-Zen Kuo, Taoyuan County (TW); Hwen-Fen Hong, Taoyuan County (TW); Yen-Cheng Tzeng, Taoyuan County (TW)

Correspondence Address: TROXELL LAW OFFICE PLLC, SUITE 1404, 5205 LEESBURG PIKE, FALLS CHURCH, VA, 22041, US

(73) Assignee: High Power-Factor AC/DC Converter with Parallel Power Processing, Taoyuan (TW)

(21) Appl. No.: 11/603,044

(22) Filed: Nov. 22, 2006

(51) Int. Cl. H01L 31/00

(52) U.S. Cl. 136/259

(57) ABSTRACT

Sets of a solar cell and a lens are obtained on a surface of a solar concentrator module. The solar cell is located at a focal point of the lens. The other sets whose solar cells are replaced with lighting devices are obtained on the opposite surface of the solar concentrator module. Each later set is reversely piled up on a former set. Hence, a light shining through the later set and the former set from the lighting device is focused on the solar cell. Consequently, photoelectric characteristics of the solar concentrator module is tested with greatly reduced cost.

### FIELD OF THE INVENTION

The present invention relates to a test device; more particularly, relates to focusing light on solar cells through a solar concentrator module for obtaining photoelectric characteristics.

### DESCRIPTION OF THE RELATED ART

A prior art of a test device for a concentrator module for solar cell, as shown in FIG. 4, comprises a module of solar concentrator cells 3; and a light source 4 corresponding to a surface of the module. By adjusting a distance between the module and the light source 4, the light source 4 emits a parallel light on the solar concentrator cells 3 simulating sun light to test photoelectric characteristics of the module.

Although the prior art tests the photoelectric characteristics of the module, the light source 4 has to be located at a position far from the solar concentrator cells 3 to simulate a parallel light like a sun light; and so, the light may become too weak to be applied and the light source 4 is hard to be positioned at a required place exactly. Besides, to simulate the sun light, the light source module 4 is positioned so far away that a big space is required and so much room is wasted Hence, the prior art does not fulfill users' requests on actual use.

### SUMMARY OF THE INVENTION

The main purpose of the present invention is to emit a parallel light from a light source module to a first Fresnel lens through a second Fresnel lens to be focused on a solar cell to effectively test photoelectric characteristics of a solar concentrator module.

To achieve the above purpose, the present invention is a test device for a solar concentrator module, comprising a solar concentrator module and a light source module, where the solar concentrator module has a plurality of first Fresnel lenses and a plurality of solar cells; each first Fresnel lens has a flat surface and an indentation surface; the indentation surface of each first Fresnel lens is corresponding to the solar cell; each light source module is piled upon a solar concentrator module; the light source module comprises a plurality of lighting devices and a plurality of second Fresnel lenses; the second Fresnel lens has a flat surface and an indentation surface; the flat surface of the second Fresnel lens is corresponding to the flat surface of the first Fresnel lens; and the indentation surface is corresponding to the lighting device. Accordingly, a novel test device for a solar concentrator module is obtained.

### BRIEF DESCRIPTIONS OF THE DRAWINGS

The present invention will be better understood from the following detailed description of the preferred embodiment according to the present invention, taken in conjunction with the accompanying drawings, in which

FIG. 1 and FIG. 2 are the perspective view and the explosive view respectively showing the preferred embodiment according to the present invention;

FIG. 3 is the sectional view showing the state of use; and

FIG. 4 is the sectional view of the prior art.

### DESCRIPTION OF THE PREFERRED EMBODIMENT

The following description of the preferred embodiment is provided to understand the features and the structures of the present invention.

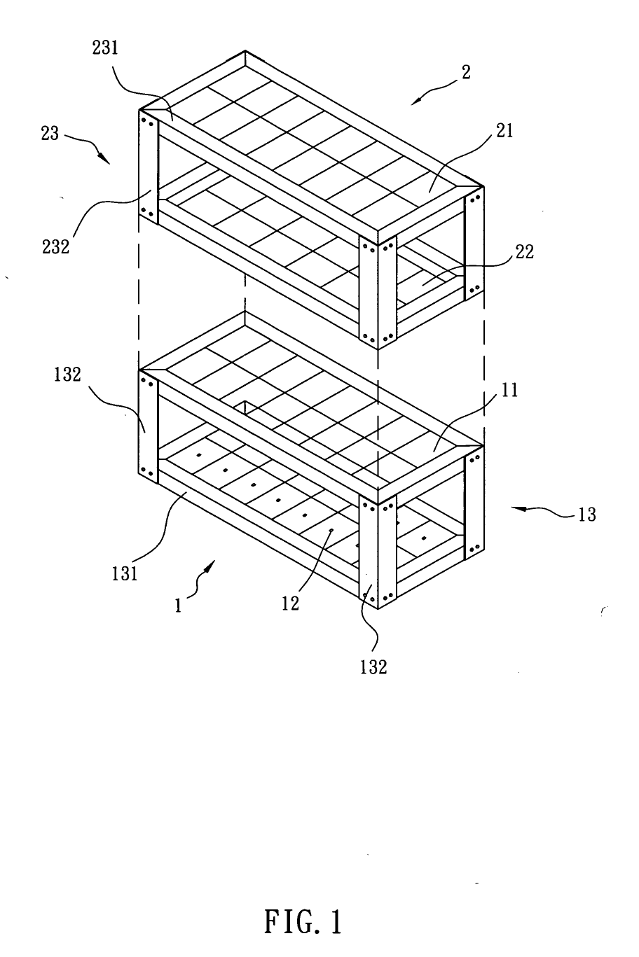

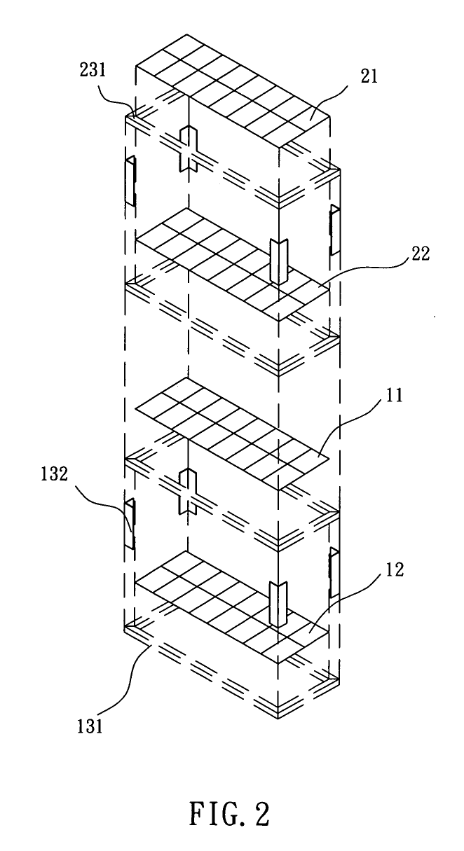

Please refer to FIG. 1 and FIG. 2, which are a perspective view and an explosive view showing the preferred embodiment according to the present invention. As shown in the figures, the present invention is a test device for a solar concentrator module, comprising a solar concentrator module 1 and a light source module 2, where light emitted from the light source module 2 is focused on solar cells 12 of the solar concentrator module 1 to effectively test photoelectric characteristics of the solar concentrator module 1.

The solar concentrator module 1 comprises a plurality of first Fresnel lenses 11 and a plurality of the solar cells 12, where the plurality of the first Fresnel lenses 11 and the plurality of the solar cells 12 are separately deposed on two opposite surfaces of a framework 13; the framework 13 is constructed by connecting a plurality of horizontal bars 131 and a plurality of vertical bars 132; the first Fresnel lens 11 has a flat surface 111 and a n indentation surface 112; and the indentation surface 112 of the first Fresnel lens 11 is corresponding to the solar cell 12.

The light source module 2 is piled up on the solar concentrator module 1. The light source module 2 comprises a plurality of lighting devices 21 and a plurality of second Fresnel lenses 22; the plurality of the lighting devices 21 and the plurality of the second Fresnel lenses 22 are deposed on two opposite surfaces of a framework 23; the framework 23 is constructed by connecting a plurality of horizontal bars 231 and a plurality of vertical bars 232; the second Fresnel lens 22 has a flat surface 221 and an indentation surface 222; the flat surface 221 of the second Fresnel lens 22 is corresponding to the flat surface 111 of the first Fresnel lens 11; the indentation surface 222 of the second Fresnel lens 22 is corresponding to the lighting device 21; and, the lighting device 21 is a light emitting diode, a fiber optic illuminator or a light bulb. Thus, a novel test device for a solar concentrator module is obtained.

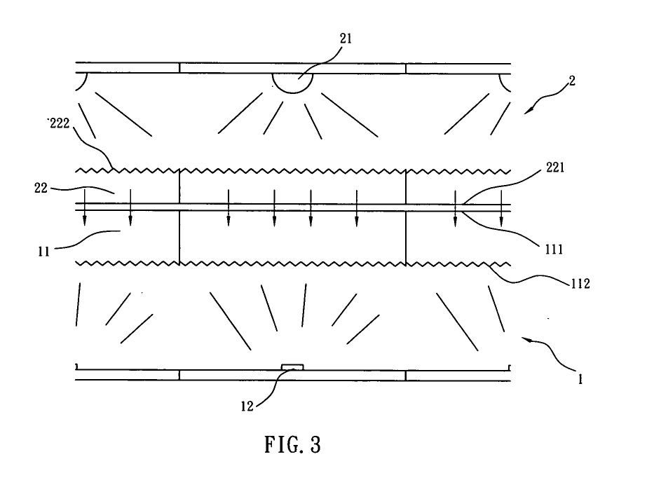

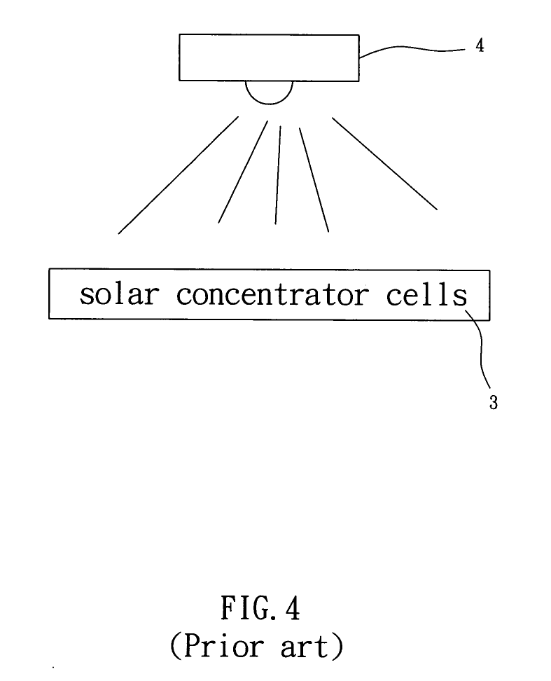

Please refer to FIG. 3, which is a sectional view showing a state of use. As shown in the figure, when using the present invention, a plurality of lighting devices 21 of a light source module 2 emits light source directly lighting on indentation surfaces 222 of second Fresnel lenses 22 through flat surfaces 221 of the second Fresnel lenses 22. With a characteristic of the second Fresnel lenses 22, parallel light source is obtained. The parallel light source enters from flat surfaces 111 of first Fresnel lenses 11 to be emitted out of indentation surfaces 112 of the first Fresnel lenses 11. At the moment, the parallel light source is changed to be focusing light owing to a characteristic of the first Fresnel lenses 11. Then the focusing light is focused on solar cells 12 of a solar concentrator module 1 to effectively test photoelectric characteristics of the solar concentrator module 1.

In the other hand, another main characteristic of the present invention is described as follows. The light source module 2 is obtained by replacing the solar cells 12 of the solar concentrator module 1 with the lighting devices 21, located at focal points of the solar cells 12 of the solar concentrator module 1. Then the light source module 2 reversed is piled up on the solar concentrator module 1 to obtain the present invention. By doing so, photoelectric characteristics of the solar concentrator module 1 are tested with greatly reduced cost.

To sum up, the present invention is a test device for a solar concentrator module, where parallel light is emitted from a light source module to first Fresnel lenses through second Fresnel lenses to be focused on solar cells to effectively test photo electric characteristics of the solar concentrator module.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A test device for a solar concentrator module, comprising:
a solar concentrator module, said solar concentrator module comprising a plurality of first Fresnel lenses and a plurality of solar cells, said first Fresnel lens having a flat surface and an indentation surface, said indentation surface of said first Fresnel lens being corresponding to said solar cell; and
a light source module, said light source module being piled up on said solar concentrator module, said light source module comprising a plurality of lighting devices and a plurality of second Fresnel lenses, said second Fresnel lens having a flat surface and a n indentation surface, said indentation surface of said second Fresnel lens being corresponding to said lighting device, said flat surface of said second Fresnel lens being corresponding to said flat surface of said first Fresnel lens.

2. The device according to claim 1,
wherein said first Fresnel lens of said solar concentrator module and said solar cell of said solar concentrator module are separately deposed on two opposite surfaces of a framework.

3. The device according to claim 2,
wherein said framework is obtained by connecting a plurality of horizontal bars and a plurality of vertical bars.

4. The device according to claim 1,
wherein said second Fresnel lens of said light source module and said lighting device of said light source module are separately deposed on two opposite surfaces of a framework.

5. The device according to claim 4,
wherein said framework is obtained by connecting a plurality of horizontal bars and a plurality of vertical bars.

6. The device according to claim 1,
wherein said lighting device is a light emitting diode.

7. The device according to claim 1,
wherein said lighting device is a fiberoptic illuminator.

8. The device according to claim 1,
wherein said lighting device is a light bulb.
